(19) United States
(12) Patent Application Publication
(10) Pub. No.: US 2024/0431035 A1
(43) Pub. Date: Dec. 26, 2024

(54) PRINTED CIRCUIT BOARD FOR COB IC CARD AND METHOD OF TREATING SURFACE OF THE PRINTED CIRCUIT BOARD FOR THE COB IC CARD

(71) Applicant: HAESUNG DS CO., LTD., Gyeongsangnam-do (KR)

(72) Inventors: Myeong Jin HAN, Gyeongsangnam-do (KR); Min Young HONG, Gyeongsangnam-do (KR)

(21) Appl. No.: 18/744,851

(22) Filed: Jun. 17, 2024

(30) Foreign Application Priority Data
Jun. 22, 2023 (KR) 10-2023-0080562

(51) Int. Cl. H05K 3/18; H05K 1/03; H05K 1/09

(52) U.S. Cl. CPC H05K 3/188; H05K 1/09; H05K 1/0313; H05K 2201/0355

(57) ABSTRACT

A method of treating a surface of a printed circuit board (PCB) for a chip on board (COB) integrated circuit (IC) card includes generating a flexible copper foil laminated film by laminating copper foils on opposite sides of an insulating layer, forming a circuit pattern layer on opposite sides of the flexible copper foil laminated film, laminating nickel through electroplating on the opposite sides of the flexible copper foil laminated film having formed thereon the circuit pattern layer, and electroplating a copper-tin (CuSn) compound layer on a contact side on which the flexible copper foil laminated film having electroplated thereon nickel is exposed to outside.

### CROSS-REFERENCE TO RELATED APPLICATION

This application is based on and claims priority under 35 USC § 119 to Korean Patent Application No. 10-2023-0080562, filed on Jun. 22, 2023, in the Korean Intellectual Property Office, the disclosure of which is incorporated by reference herein in its entirety.

### BACKGROUND

### 1. Field

The disclosure relates to a method of treating a surface of a printed circuit board (PCB) for a chip on board (COB) integrated circuit (IC) card.

### 2. Description of the Related Art

A chip on board (COB) integrated circuit (IC) card refers to a printed circuit board (PCB) that has mounted thereon an IC chip storing information required for mobile devices, credit cards, etc. to transmit stored security information through an electrical signal.

### SUMMARY

Provided are a printed circuit board (PCB) for a chip on board (COB) integrated circuit (IC) card and a method of treating a surface of the PCB for the COB IC card in which a compound layer having excellent chemical resistance and implementing same color as a precious metal is used as a surface of the PCB for the COB IC card.

Additional aspects will be set forth in part in the description which follows and, in part, will be apparent from the description, or may be learned by practice of the presented embodiments of the disclosure.

According to an aspect of the disclosure, a method of treating a surface of a printed circuit board (PCB) for a chip on board (COB) integrated circuit (IC) card includes generating a flexible copper foil laminated film by laminating copper foils on opposite sides of an insulating layer, forming a circuit pattern layer on opposite sides of the flexible copper foil laminated film, laminating nickel through electroplating on the opposite sides of the flexible copper foil laminated film having formed thereon the circuit pattern layer, and electroplating a copper-tin (CuSn) compound layer on a contact side on which the flexible copper foil laminated film having electroplated thereon nickel is exposed to outside.

In an embodiment of the disclosure, a ratio of Cu to Sn in the CuSn compound layer is set such that a color of the CuSn compound layer is the same as a color of gold (Au) or palladium (Pd).

### BRIEF DESCRIPTION OF THE DRAWINGS

The above and other aspects, features, and advantages of certain embodiments of the disclosure will be more apparent from the following description taken in conjunction with the accompanying drawings, in which:

FIGS. 1 and 2 show an example of a structure for treating a surface of a chip on board (COB) printed circuit board (PCB) according to an embodiment of the disclosure; and

FIG. 3 is a flowchart of a method of treating a surface of a COB integrated circuit (IC) card, according to an embodiment of the disclosure.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description.

The disclosure may have various modifications thereto and various embodiments, and thus particular embodiments will be illustrated in the drawings and described in detail in a detailed description. Effects and features of the disclosure, and methods for achieving them will become clear with reference to matters described later in detail together with the drawings. However, the disclosure is not limited to the embodiments disclosed below and may be implemented in various forms.

Hereinafter, the following embodiments will be described in detail with reference to the accompanying drawings, and in description with reference to the drawings, the same or corresponding components are given the same reference numerals, and redundant description thereto will be omitted.

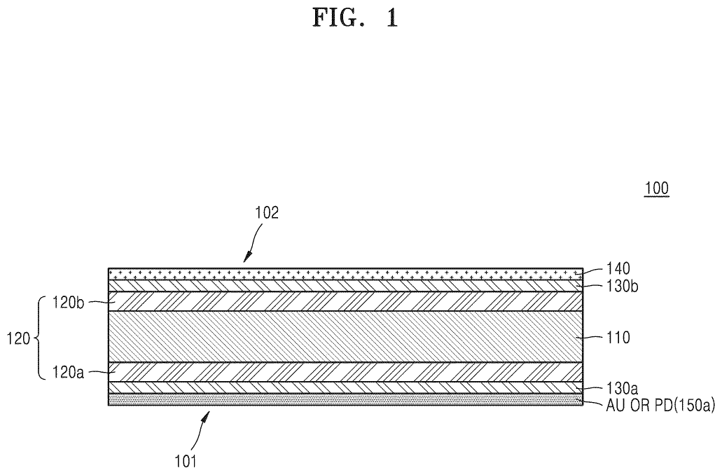

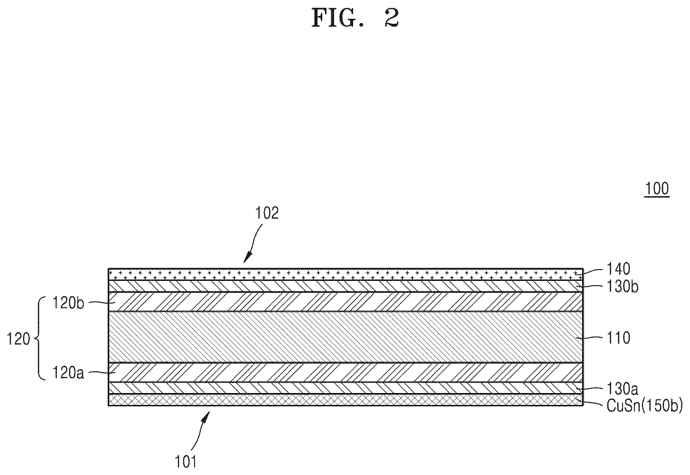

FIGS. 1 and 2 show an example of a structure for treating a surface of a chip on board (COB) printed circuit board (PCB) according to an embodiment of the disclosure.

A COB integrated circuit (IC) card 100 may include a bonding side 101 for wire bonding or flip chip bonding and a contact side 102 exposed to outside. Surface treatment of the contact side 102 is important as it is necessary that an exterior surface of the COB IC card 100 has a high resistance to chemical resistant substances to prevent discoloration. In an embodiment of the disclosure, a metal alloy having a high resistance to chemical resistant substances may be stacked on a surface layer of the contact side 102. An example of the metal alloy may include copper-tin (CuSn).

A description will be made with reference to FIG. 1.

In an embodiment of the disclosure, the COB IC card 100 may include an insulating layer 110, a flexible copper foil laminated film 120 generated by laminating copper foils 120a and 120b on opposite sides of the insulating layer 110, nickel layers 130a and 130b electroplated on opposite sides of the flexible copper foil laminated film 120, and a CuSn compound layer 140 electroplated on the nickel layer 130b in a direction exposed to the outside.

To electroplate the CuSn compound layer 140, a pre-treatment process for washing the nickel layer 130b is required. A board surface of the nickel layer 130b may be cleaned through an alkaline degreasing process to electroplate the CuSn compound layer 140. After electroplating, anti-tarnishing treatment may be performed to prevent discoloration.

In another embodiment of the disclosure, in the COB IC card 100, the insulating layer 110, the flexible copper foil laminated film 120 generated by laminating the copper foils 120a and 120b on the opposite sides of the insulating layer 110, and the CuSn compound layer 140 on the flexible copper foil laminated film 120 may be electroplated.

In an embodiment of the disclosure, a plating solution for generating the CuSn compound layer 140 may need to have a temperature of about 18° C. to about 22° C. and a pH of 1 or less. As an anode, an insoluble anode may be used. An alloy amount of a CuSn compound may be controlled by a current density applied during plating. As the applied current density increases, a content of copper may increase. In this case, an available current density may be 1 to 6 ampere per square decimeter (ASD), and a recommended current density may be about 1 ASD to about 2 ASD. In a current density period of about 1 ASD to about 6 ASD, the CuSn compound layer 140 having the same color as palladium (Pd) may be implemented.

In an embodiment of the disclosure, to implement the same color of the CuSn compound as palladium (Pd), a rate of Cu may be set to about 55% to about 70% and a rate of Sn may be set to about 30% to about 45%.

In another embodiment of the disclosure, to implement the same color of the CuSn compound as gold (Au), a rate of Cu may be set to about 80% to about 90% and a rate of Sn may be set to about 10% to about 20%.

In the COB IC card 100, precious metal may be laminated 150a on the bonding side 101 through electroplating. An example of precious metal may include Au or Pd. In another embodiment of the disclosure, in the COB IC card 100, the CuSn compound layer 150b may be electroplated on the nickel layer 130a on the bonding side 101 like in the embodiment of FIG. 2.

Table 1 shows test conditions of the international standards test to determine whether various chemical contaminants have adverse effects on a COB card plated with a CuSn compound layer. A standards number is KSXISOIEC10373-1. In an embodiment of the disclosure, the COB IC card 100 of FIG. 1 or 2 has passed a test for checking discoloration of the exterior after dipping into 9 types of compounds as shown in Table 1.

TABLE 1
Test Conditions
(25 ± 2) ° C.,
Dipping into 5% sodium chloride
solution for 1 min
(25 ± 2) ° C.,
Dipping into 5% acetic acid
solution for 1 min
(25 ± 2) ° C.,
Dipping into 5% sodium carbonate
solution for 1 min
(25 ± 2) ° C.,
Dipping into 60% ethyl alcohol
solution for 1 min
(25 ± 2) ° C.,
Dipping into 10% sucrose solution
for 1 min
(25 ± 2) ° C.,
Dipping into fuel B solution
for 1 min
(25 ± 2) ° C.,
Dipping into 50% ethylene glycol
solution for 1 min
(25 ± 2) ° C.,
Dipping into alkaline solution
for 24 hrs
(25 ± 2) ° C.,
Dipping into acid solution
for 24 hrs

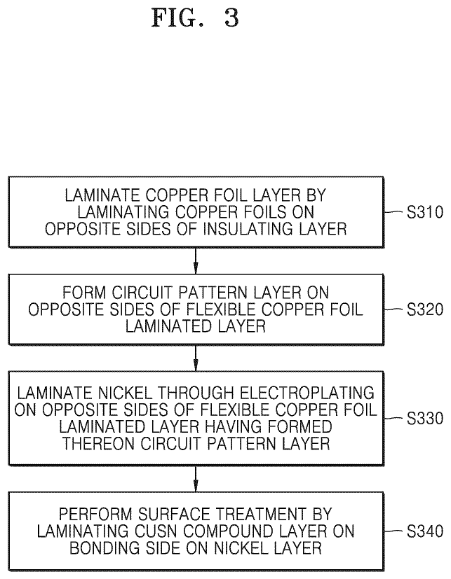

FIG. 3 is a flowchart of a method of treating the surface of the COB IC card 100, according to an embodiment of the disclosure.

A copper foil layer may be laminated by laminating electrolytic copper foils on opposite sides of an insulating layer. Thus, a flexible copper foil laminated film may be generated, in operation S310. An example of the insulating layer may include epoxy-based polymer series. For example, there may be polyimide resin film materials and polyethylene naphthalate resin films.

A circuit pattern layer may be formed on opposite sides of the flexible copper foil laminated film, in operation S320. In this case, the same pattern processing may be applied to a bonding side and a contact side. For the circuit pattern layer, dry film photoresist (DFR) may be applied and exposure and development processes may be performed. After completion of the development process, etching may be performed to form a pattern and the DFR may be delaminated to form a circuit pattern.

Nickel may be laminated through electroplating on the opposite sides of the flexible copper foil laminated film having formed thereon the circuit pattern layer, in operation S330. By forming nickel or a nickel compound layer on the opposite sides of the PCB on which the circuit pattern layer is formed, diffusion of Cu over the surface may be prevented.

Surface treatment for electroplating a CuSn compound layer on the contact side on the nickel layer may be performed, in operation S340. Through surface treatment, corrosion due to an external environment and resistance to chemical resistant substances may be provided, thereby protecting the board.

In an embodiment of the disclosure, by controlling a ratio of Cu to Sn in the CuSn compound layer, the same color as Au or Pd may be implemented.

Thereafter, anti-tarnishing processing may be performed on the CuSn compound layer, thereby preventing oxidation, in operation S350.

The method according to an embodiment of the disclosure may be implemented in the form of program commands that may be executed through various computer means and recorded on a computer-readable recording medium. The computer-readable recording medium may include a program command, a data file, a data structure and the like solely or in a combined manner. The program command recorded in the computer-readable recording medium may be a program command specially designed and configured for the disclosure or a program command known to be used by those skilled in the art of the computer software field.

While the disclosure has been described with reference to limited embodiments and drawings, the disclosure may not be limited to the foregoing embodiments, and it would be obvious to those of ordinary skill in the art that various modifications and changes may be possible from the disclosure.

According to an embodiment of the disclosure, by plating the surface of the PCB for the COB IC card with a CuSn compound layer, a manufacturing cost may be reduced and a board having excellent chemical resistance may be manufactured.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A method of treating a surface of a printed circuit board (PCB) for a chip on board (COB) integrated circuit (IC) card, the method comprising:
generating a flexible copper foil laminated film by laminating copper foils on opposite sides of an insulating layer;
forming a circuit pattern layer on opposite sides of the flexible copper foil laminated film;
laminating nickel through electroplating on the opposite sides of the flexible copper foil laminated film having formed thereon the circuit pattern layer; and
electroplating a copper-tin (CuSn) compound layer on a contact side on which the flexible copper foil laminated film having electroplated thereon nickel is exposed to outside.

2. The method of claim 1, wherein a ratio of Cu to Sn in the CuSn compound layer is set such that a color of the CuSn compound layer is same as a color of gold (Au) or palladium (Pd).

3. The method of claim 1, further comprising electroplating a CuSn compound layer on a bonding side of the flexible copper foil laminated film having electroplated thereon nickel.

4. The method of claim 1, further comprising laminating a precious metal layer on the bonding side of the flexible copper foil laminated film having laminated thereon nickel.

5. A printed circuit board (PCB) for a chip on board (COB) integrated circuit (IC) card, the PCB comprising:
a flexible copper foil laminated film generated by laminating copper foils on opposite sides of epoxy resin;
nickel layers electroplated on opposite sides of the flexible copper foil laminated film; and
a copper-tin (CuSn) compound layer electroplated on a first nickel layer electroplated in a direction exposed to outside between the nickel layers electroplated on the opposite sides.

6. The PCB of claim 5, further comprising a precious metal layer electroplated under a second nickel layer electroplated in a direction in which bonding is performed between the nickel layers electroplated on the opposite sides.

7. The PCB of claim 5, further comprising a CuSn compound layer electroplated under the second nickel layer electroplated in the direction in which bonding is performed between the nickel layers electroplated on the opposite sides.

8. The PCB of claim 1, wherein a ratio of Cu to Sn in the CuSn compound layer is set such that a color of the CuSn compound layer is same as a color of gold (Au) or palladium (Pd).

9. The PCB of claim 5, wherein an amount of an alloy is controlled by a current density applied during plating of a CuSn compound.

10. The PCB of claim 5, wherein a temperature of a plating solution for generating the CuSn compound layer is about 18° C. to about 22° C., a pH of the plating solution is maintained as 1 or less, and an insoluble anode is used as an anode.

11. The PCB of claim 9, wherein a color of the CuSn compound is same as a color of Pd by applying about 1 ASD to about 6 ASD as the current density.
